(19) United States
(12) Patent Application Publication
(10) Pub. No.: US 2024/0418782 A1
(43) Pub. Date: Dec. 19, 2024

(54) Method for Assessing an Electrical Storage Cell

(71) Applicant: Siemens Aktiengesellschaft, München (DE)

(72) Inventors: Sascha Schulte, Höchstadt (DE); Manfred Baldauf, Erlangen (DE)

(73) Assignee: Siemens Aktiengesellschaft, München (DE)

(21) Appl. No.: 18/704,203

(22) PCT Filed: Oct. 12, 2022
(86) PCT No.: PCT/EP2022/078344

§ 371 Date: Apr. 24, 2024

(30) Foreign Application Priority Data
Oct. 25, 2021 (EP) 21204511.6

(51) Int. Cl. G01R 31/367; G01R 31/392

(52) U.S. Cl. CPC G01R 31/367; G01R 31/392

(57) ABSTRACT

Various embodiments of the teachings herein include a method for assessing an electrical storage cell. An example includes: creating a data set relating to the ageing behavior of an reference cell of a specific type with regard to charging and discharging; creating a second data set of a second reference cell of the same type; measuring an electrochemical operating characteristic of each reference storage cell and linking this operating characteristic to the reference data set; saving at least two reference data sets to the operating characteristic in a database; measuring the electrochemical operating characteristic of a storage cell; comparing the measured operating characteristic of the storage cell with the reference storage cells; and assigning the storage cell on the basis of an assignment key to one of the operating characteristics saved in the database and the reference data set linked thereto.

### CROSS-REFERENCE TO RELATED APPLICATIONS

This application is a U.S. National Stage Application of International Application No. PCT/EP2022/078344 filed Oct. 12, 2022, which designates the United States of America, and claims priority to EP application Ser. No. 21/204,511.6 filed Oct. 25, 2021, the contents of which are hereby incorporated by reference in their entirety.

### TECHNICAL FIELD

The present disclosure relates to electrical storage. Various embodiments of the teachings herein include methods and/systems for assessing an electrical storage cell.

### BACKGROUND

The operational management of batteries and battery cells benefits in important respects (service life, costs, etc.) from knowing as precisely as possible the relationship between type of use and ageing. An important description of this relationship is given by families of ageing curves, sometimes also referred to as stress-number curves after an equivalent in the field of mechanical engineering, in which the anticipated service life is assigned to a cycle depth (DoD).

The calculation of these families of ageing curves is very expensive using conventional methods, and sometimes even involves the destruction of the storage cell being tested. For example, using a cell with various depths of discharge (DoD) and various states of charge (SoC), provision is made to measure the maximum possible number of charging cycles before the corresponding storage cell fails. This is repeated for each data point in the family of curves using a multiplicity of storage cells, and an average value is calculated for each point from the tested storage cells. This approach is clearly useful for drawing conclusions about the load range in which a type of storage cell should typically be used. However, this family of curves must be prepared for each type of storage cells, and small changes to the design and construction or production usually require a corresponding family of ageing curves to be prepared again.

This gives rise to a conflict of interests in the wish to individually assign such a measurement to each storage cell that is delivered and thereby allow optimal open-loop and closed-loop control of each battery. Alternatively, such a measurement can be assigned generally to the respective model type, without considering the individual variations in this case.

### SUMMARY

The teachings of the present disclosure provide testing systems and/or methods for a storage cell, which method places only a slight load on the storage cell and is highly revealing in respect of the individual electrochemical characteristic thereof. As an example, some embodiments include a method for assessing an electrical storage cell (2), comprising: a) creating a reference data set (4) relating to the ageing behavior of an individual reference storage cell (6) of a specific type with regard to the charging and discharging behavior thereof, b) creating a second reference data set (4′) of a second reference storage cell (6′) of the same type, c) measuring an electrochemical operating characteristic (8, 8′) of each reference storage cell (6, 6′) for which a reference data set (4, 4′) is created, and linking this operating characteristic (8, 8′) to the reference data set (4, 4′) thereof, d) saving at least two reference data sets (4, 4′) of at least two reference storage cells (6, 6′) of the same type and the associated links to the operating characteristic (8, 8′) in a database (10), e) measuring the electrochemical operating characteristic (8′) of a storage cell (2), f) comparing the measured operating characteristic (8″) of the storage cell (2) with the operating characteristics (8, 8′) of the reference storage cells (6, 6′) saved in the database (10), and g) assigning the storage cell (2) on the basis of an assignment key (22) to one of the operating characteristics (8, 8′) saved in the database (10) and the reference data set (4, 4′) linked thereto.

In some embodiments, data points (14) in the reference data set (4, 4′) relating to the ageing behavior link three variables to each other, namely a depth of discharge (DoD), a state of charge (SoC) and a number of equivalent full cycles (N) of the reference storage cell that is possible for this.

In some embodiments, the reference data set (4) contains at least five data points with linking of the three variables.

In some embodiments, at least five reference data sets (4, 4′) with the respectively corresponding operating characteristics (8, 8′) are saved in the database (10).

In some embodiments, the reference data set relating to the ageing behavior is created by: a) measuring at least two load cycles of the battery store by means of a high-precision coulometer, wherein one load cycle comprises a first discharging, during which a first charge amount from a first charge state to a second charge state is measured, followed by a first charging, during which a second charge amount from the second charge state to a third charge state is measured, and a second discharging, during which a third charge amount from the third charge state to a fourth charge state is measured, wherein the charging and discharging of the load cycle occurs between a lower voltage and an upper voltage of the battery store, b) ascertaining a first charge transfer by means of a difference between the fourth charge state and the second charge state, and ascertaining a second charge transfer by means of a difference between the third charge state and the first charge state, c) ascertaining a capacitance loss from the difference between the first charge transfer and the second charge transfer, performing a) to c) until the capacitance loss is almost constant in at least two consecutive load cycles, and determining an average capacitance loss on the basis of at least two capacitance losses.

In some embodiments, the determination of the electrochemical operating characteristic (8) takes the form of an electrochemical impedance spectroscopy (16).

In some embodiments, the determination of the electrochemical operating characteristic is effected by considering discrete frequencies of an impedance spectrum that is obtained by means of the impedance spectroscopy.

In some embodiments, the determination of the electrochemical operating characteristic (8) is effected by means of a method as claimed in claims 5 a) to 5 c).

In some embodiments, following the assignment of a storage cell to a reference data set, a usage specification of the storage cell in a battery storage system is produced.

In some embodiments, electrochemical quality classes for the storage cells (2) are defined and, after assigning the storage cell to a reference data set (4, 4′), the storage cell (2) is assigned to a quality class.

In some embodiments, a quality criterion for the quality classes is characterized by the maximum number of equivalent full cycles in the reference data set (4).

In some embodiments, the quality criterion is characterized by the volume beneath the family of curves which is formed by the reference data set.

### BRIEF DESCRIPTION OF THE DRAWINGS

Further embodiment variants and further features of the teachings herein are explained in greater detail below with reference to the appended figures. These are schematic representations and exemplary embodiment variants, and do not restrict the scope of the disclosure. In the figures:

FIG. 1 shows a family of ageing curves for a type of storage cells according to the prior art, in which a plurality of storage cells are examined for each point in the curve profile;

FIG. 2 shows a reference data set of the ageing behavior of an individual reference storage cell in the upper part, and a corresponding representation of an EIS measurement of the same cell in the lower part incorporating teachings of the present disclosure;

FIG. 3 shows the reference data set of a further reference storage cell in a similar representation to FIG. 2;

FIG. 4 shows the reference data set of yet another reference storage cell in a similar representation to FIGS. 2 and 3; and

FIG. 5 shows a schematic representation of a practical application of the combinations of the reference data set and the operating characteristic incorporating teachings of the present disclosure.

### DETAILED DESCRIPTION

An example method includes: a) creating a reference data set relating to the ageing behavior of an individual reference storage cell of a specific type with regard to the charging and discharging behavior thereof, b) creating a further reference data set of a second reference storage cell of the same type, c) measuring an electrochemical operating characteristic of each reference storage cell for which a reference data set is created, and linking this operating characteristic to the respective reference data set, d) saving at least two reference data sets of at least two reference storage cells of the same type and the associated links to the operating characteristic in a database, e) measuring the electrochemical operating characteristic of a storage cell, f) comparing the measured operating characteristic of the storage cell with the operating characteristics of the reference storage cells saved in the database, and g) assigning the storage cell on the basis of an assignment key to one of the operating characteristics saved in the database and the reference data set linked thereto.

The ageing curves, in the form of the reference data set based on average values, are not performed for a multiplicity of storage cells, and no average value is formed from the measured values or measured curves of the individual reference storage cells. Instead, only one reference storage cell is used in each case, from which a reference data set relating to the ageing behavior thereof is created in each case. The information relating to the reference storage cell (reference data set) is additionally linked to a metrologically determined electrochemical operating characteristic thereof.

The term two or more storage cells “of the same type” signifies storage cells which are substantially identical structurally but which nonetheless differ within the bounds of production tolerances. In particular, the electrochemical composition of the individual storage cells is identical within the bounds of manufacturing tolerances. The reference storage cells and the storage cells assessed by means of the method are therefore of the same type.

Subsequently, storage cells under consideration whose characteristic is tested, for example, following the manufacture thereof, need only be tested in respect of an electrochemical operating characteristic, this being relatively undemanding to determine technically and placing only minimal load on the cell. In this way, from the saved database in which are saved a plurality of (at least two) tested reference storage cells with their respective reference data sets relating to the ageing behavior and corresponding operating characteristic, it is possible to infer the reference data set which best matches the operating characteristic of the storage cell under consideration. It has been discovered that the cells having storage similar electrochemical operating characteristics exhibit similar ageing behavior. The link between two storage cells having similar operating characteristics is therefore suitable for inferring with adequate approximation the ageing behavior of the corresponding reference storage cell and the reference data set thereof, this being then used for a storage cell under consideration.

Following consideration of this best possible match, it is possible, for example, to produce a usage specification for the storage cell in a battery storage system. In some embodiments, the storage cell under consideration can be linked to an optimal control instruction, which can then be taken into account individually when the cell is subsequently integrated into a larger system.

In some embodiments, three variables are linked to each other for data points in the reference data set relating to the ageing behavior, namely a depth of discharge (DoD), a state of charge (SoC) and a number (N) of equivalent full cycles of the reference storage cell that is possible for this. Equivalent charging cycles are understood here in the sense that e.g. 10 charging cycles to 10% correspond to one equivalent full cycle, and similarly four cycles to 25% correspond to one equivalent full cycle. Such a combination of data points results in a substantial amount of information content being transferred to the further control of the storage cell under consideration. It is appropriate in this case to record at least five such data points in a reference data set. This means that the maximum charging cycles of the reference storage cell should be determined in each case for at least five combinations of SoC and DoD.

In some embodiments, it would also be possible to record the current strength of the charge current or discharge current and/or the temperature during the charging or discharging process as data points in the reference data set.

The number of reference storage cells under consideration and the resulting number of corresponding reference data sets should be as large as possible in that each storage cell under consideration has the largest possible selection for the best possible assignment of the operating characteristic thereof. On the other hand, the considerable technical overheads and hence the high cost overheads favor the smallest possible number of reference data sets for reference storage cells, and therefore at least two reference storage cells are considered and stored in the database, though the reference data sets of at least five reference storage cells may be stored in the database. With at least 20 reference data sets from 20 reference storage cells, a very good selection of reference data sets is available for a good assignment of the storage cells being tested.

In some embodiments, a method for determining at least one average capacitance loss of a reference storage cell comprises: a) measuring at least two load cycles of the battery store by means of a high-precision coulometer (HPC), wherein a single load cycle comprises a first discharging during which a first charge amount from a first charge state to a second charge state is measured. This is followed by a first charging, during which a second charge amount from the second charge state to a third charge state is measured. This is followed by a second discharging, during which a third charge amount from the third charge state to a fourth charge state is measured. The charging and discharging in the load cycle takes place between a lower voltage and an upper voltage of the battery store. The example includes b) ascertaining a first charge transfer by means of a difference between the fourth charge state and the second charge state and ascertaining a second charge transfer by means of a difference between the third charge state and the first charge state; and c) ascertaining a capacitance loss from the difference between the first charge transfer and the second charge transfer. Elements a), b), and c) are performed until the capacitance loss is substantially constant. The average capacitance loss is then calculated on the basis of at least two capacitance losses.

Conclusions relating to the maximum charging cycles of a reference storage cell can be made on the basis of greatly reduced charging and discharging operations. It is consequently possible by virtue of the described method to arrive significantly more quickly at meaningful values relating to the ageing behavior of the reference storage cell, without said storage cell being destroyed each time. The HPC method makes it possible to provide families of ageing curves or reference data sets for reference storage cells far more quickly and also to present these in a detailed manner.

In some embodiments, the determination of the electrochemical operating characteristic takes the form of electrochemical impedance spectroscopy (EIS). EIS is an established technical method which can be applied to storage cells without significant technical overheads and places barely any load on the storage cells with regard to the ageing thereof. EIS is a method which can be applied as a matter of course to every storage cell following manufacture. The EIS is usually represented graphically in the form of a Nyquist diagram. This method of presentation for impedances is routinely used in the field of electrical engineering and shows, for example, the real part of the impedance value as a complex number on the x-axis and the imaginary part of the impedance value on the y-axis.

In this case, it can also be appropriate for the determination of the electrochemical operating characteristic to be effected by considering discrete frequencies of an impedance spectrum obtained by means of impedance spectroscopy. For example, one to three frequencies that are characteristic of the electrochemical behavior of the storage cell can be recorded and evaluated for this purpose. It is not necessary to create a complete spectrum for this purpose, thereby saving time and manufacturing costs. The term discrete is understood in this case to mean that a very narrow but not infinitely narrow frequency range is considered, it being possible to consider said frequency range using conventional technical methods.

An alternative or additional possibility for testing the electrochemical operating characteristic of a storage cell is an HPC method as described in claim 4. As part of this activity, fewer iteration steps may be required than is the case when producing the described reference data set. In particular, it is also possible in this case to measure only one data point in the reference data set, said data point being as far as possible characteristic. As a result of the smaller number of iterations, less load is placed on the storage cell and it is nonetheless possible on the basis of the value thus measured to produce a correlation to the reference data set.

In some embodiments, the method includes defining electrochemical quality classes for the storage cells and, after assigning the storage cell to a reference data set, allocating the storage cell to a quality class. This means that the storage cells can optionally be sorted for use according to their quality class and installed in defined storage units. In this case, the storage units thus assembled feature different power classes, for example. In some embodiments, the storage cells in a storage unit can be activated individually according to their assigned quality class. This means that a storage cell which is capable of a higher number of full cycles, for example, can be selectively and singly charged and discharged during an average loading of the storage unit, while weaker storage cells are on the other hand more often conserved.

In some embodiments, the method includes using the maximum number of equivalent full cycles in the reference data set as a quality criterion for the quality classes. This can be used, for example, for selective activation of the storage cells in the storage unit as described above. As an alternative or in addition to the maximum number of full cycles, the quality criterion can be characterized by the volume beneath the family of curves that is formed by the reference data set. This criterion can also be seen as an average number of the possible full cycles over all data points in the reference data set.

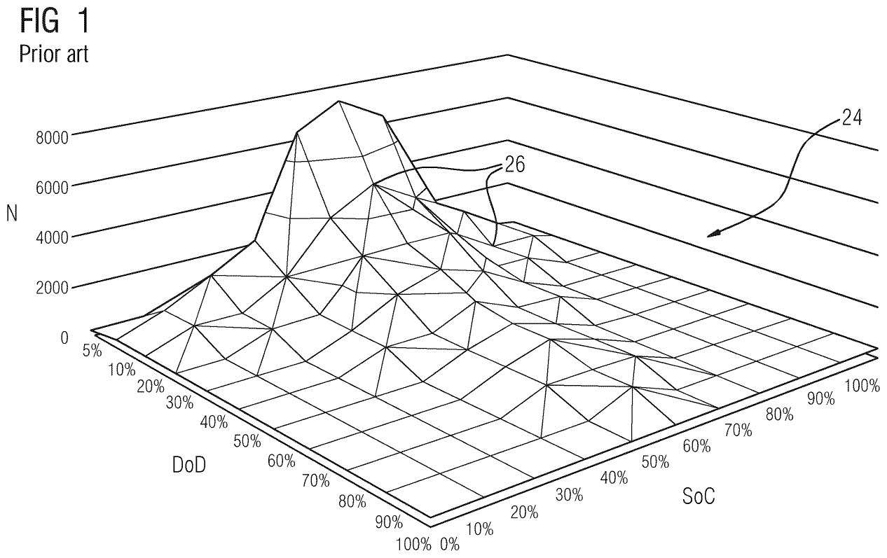

FIG. 1 illustrates a family of ageing curves 24 for electrical storage cells according to the prior art. In this case, the relationship between the depth of discharge (DoD) and the state of discharge or state of charge (SoC) is plotted on a projection plane. Plotted in a Z direction and designated N is the number of possible maximum charging cycles for the respective points in relation to DoD and SoC. The graphical representation in this case shows that the highest number of charging cycles can be achieved using a very low depth of discharge of 5%-10% around an average state of charge SoC between approximately 40% and 60%. The more deeply the storage cell is discharged, i.e. the higher the DoD, the fewer the number of charging cycles before the storage cell is destroyed.

The particularity of the graphical representation according to FIG. 1 is that a plurality of storage cells undergo this procedure for every single data point 26 represented there, and the data point 26 represents a nominal average value of the values obtained for all storage cells under consideration. For this reason, the described method is technically very resource-intensive and must be repeated for each individual type of storage cells. The number of data points 26 in the family of ageing curves 24 is therefore kept very low for reasons of economy, and such families of curves 24 are often less meaningful as a consequence. Furthermore, all of the data points 26 are average values and therefore in the case of a storage cell under consideration which has been taken from production, it is also only possible to infer on average how it will behave with the corresponding combinations of DoD and SoC. Individual consideration of a storage cell, and therefore load management which is tailored to this, is not possible on the basis of the families of curves 24 according to the prior art.

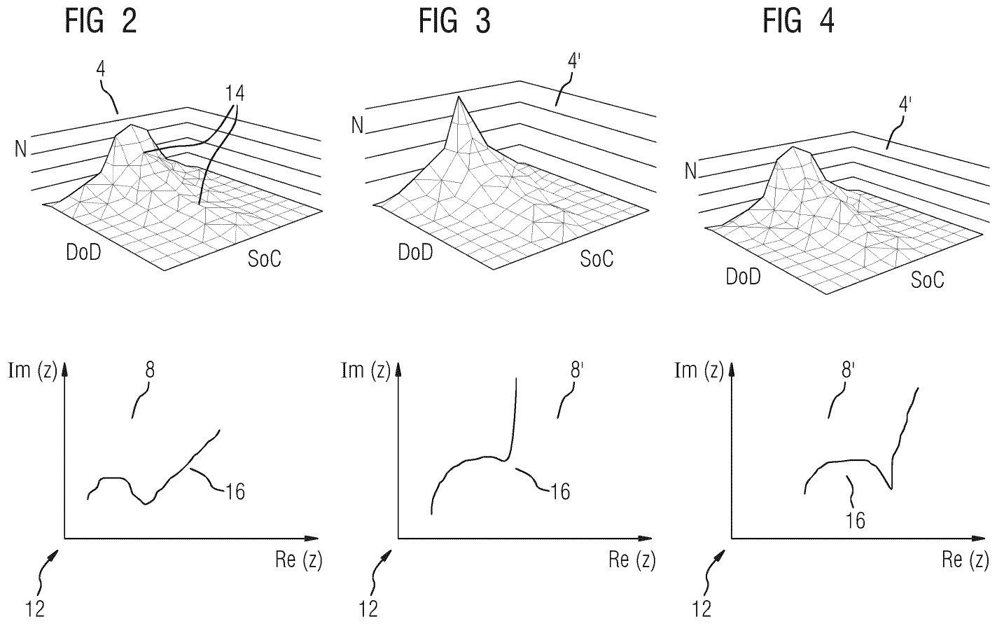

FIGS. 2 to 4 show families of curves which appear in principle to be very similar to the family of ageing curves 24 from FIG. 1, but nonetheless differ distinctly from this. The difference in the families of curves in FIGS. 2 to 4, designated as reference data sets 4, 4′ there, is that said reference data set 4 or 4′ is prepared for a reference storage cell 6, 6′ which is taken from production. Data points 14 in the illustrations according to FIGS. 2, 3 and 4 are not average values from a plurality of storage cells, but the results of measurements of a single reference storage cell 6, 6′. It should be noted that the reference sign 6′ is also used for the reference storage cell 6 in order to indicate that the storage cell is not identical. The use of further reference signs 6′ again indicates further individual storage cells which likewise differ from each other. This terminology applies to the reference data set 4, the reference storage cells 6 and the operating characteristic 8 described below.

An electrochemical operating characteristic 8, 8′ which characterizes the reference storage cell 6, 6′ is then recorded for the respective reference storage cell 6, 6′, preferably before the preparation of the reference data set 4, 4′. The so-called electrochemical impedance spectroscopy 16 was found to be the preferred operating characteristic 8. The impedance spectroscopy 16 is preferably plotted in the form of a Nyquist diagram 12 and is illustrated in the lower part of the FIGS. 2, 3 and 4 in each case. The real part of the impedance Z is represented on the x-axis here, and the imaginary part on the y-axis. This results in a characteristic operating characteristic 8, 8′ for each reference storage cell 6, 6′, which can then be assigned specifically to a reference data set 4, 4′ of this individual reference storage cell 6, 6′.

This assignment applies to all reference data sets 4, 4′ that are illustrated by way of example in the FIGS. 2, 3 and 4. It is evident here that all three reference data sets illustrated in the FIGS. 2, 3 and 4 exhibit entirely individual changes even though they are qualitatively essentially very similar. Only three different reference data sets 4, 4′ are illustrated in the FIGS. 2 to 4. In order to allow an optimal assignment of the electrical storage cells 2 originating from live production to the reference data sets 4, it is advantageous to have the largest possible number of reference data sets 4 with the correspondingly assigned operating resource characteristics 8. At least five and as many as more than 20 such pairings should be prepared in this case. With regard to the number of data points 14 in the individual reference data sets 4, it likewise applies that the largest possible number of data points 14 should be present. A minimum is considered to be five data points 14 here, and in some cases more than 20 data points are prepared.

For the purpose of preparing the data points 14 in the described method, it is possible to use a conventional test series of discharging and charging processes which ultimately result in the destruction of the reference storage cell 6. With regard to optimizing the technical overheads, it is however possible to use the HPC method described above. In this way, the reference data set 4 is created with considerably fewer technical overheads. The described HPC method can, with a smaller number of iteration steps, also be used as an alternative or in addition to the impedance spectroscopy method 16 as an operating characteristic 8.

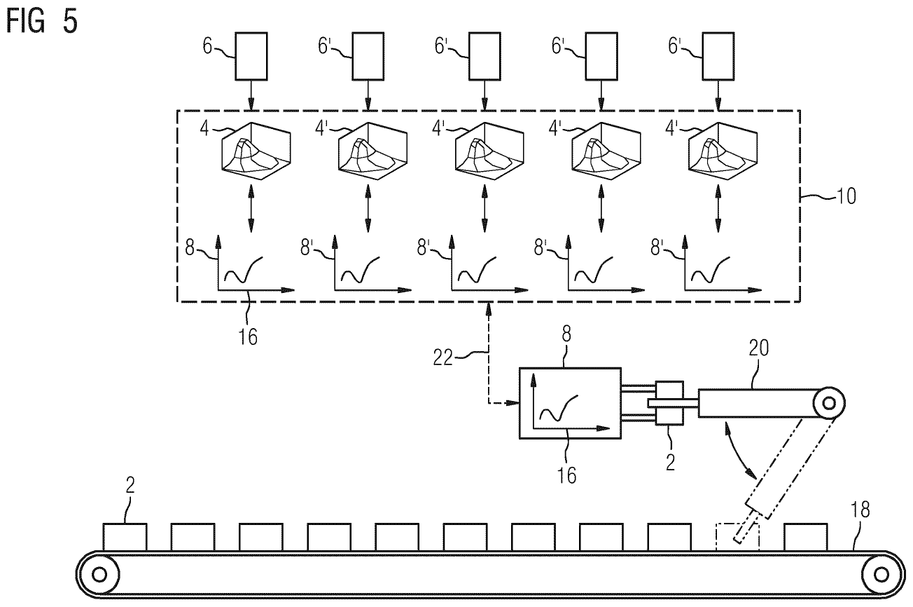

FIG. 5 schematically illustrates a practical application of the combinations of reference data set 4 and operating characteristic 8 incorporating teachings of the present disclosure. In the upper part of FIG. 5, a plurality of reference storage cells 6, 6′ have been examined and a reference data set 4 with a corresponding operating characteristic 8 prepared and represented in each case by means of impedance spectroscopy 16. The total number of combinations comprising reference data sets 4 and operating characteristics 8 for each examined reference storage cell 6 are saved in a database 10, this being indicated in FIG. 5 as a broken-line box around the total number of graphs.

If a multiplicity of storage cells 2 from production are now examined in respect of their electrochemical characteristic, as indicated in the lower part of FIG. 5 with the aid of a conveyor line 18 on which a multiplicity of storage cells 2 are conveyed, each individual one of these storage cells 2 is preferably examined in respect of its operating characteristic 8. This is schematically illustrated in FIG. 5 by means of a robot device 20. This means that an electrochemical impedance spectroscopy 16 is preferably prepared for each storage cell 2. The preparation of the impedance spectroscopy 16 signifies barely any electrochemical load on the storage cell 2, and consequently returns an operating characteristic 8 which can be compared with the operating characteristics 8, 8′ in the database 10. As part of this activity, use is made of an assignment key 22 which is indicated in FIG. 5 by the broken-line dual-headed arrow. The assignment key can be an artificial intelligence program which is designed specifically for the corresponding graphs, and searches for best possible similarities and matches according to empirical criteria. If a best possible match of the measured operating characteristic 8 of the storage cell 2 with an operating characteristic 8 from the database 10 is identified, is it possible to infer with a good degree of accuracy an ageing behavior as per the assigned reference data set 4.

For any desired storage cell 2 following manufacture, an individual family of ageing curves in the form of the reference data set 4 can be assigned with a high degree of accuracy. These are not probabilities derived from average values on the basis of which the type of storage cells specifically ages, but rather a means of making individual predictions for the individual storage cell 2 under consideration. In this, the described method differs explicitly from the prior art, in which only average probabilities for the ageing behavior are specified.

It is therefore also possible, for each individual storage cell 2, to assign an individual load management for the use thereof. This means that in the case of a storage cell 2 which is individually embodied as somewhat weaker than another in respect of ageing behavior, individual storage management can take place in a subsequent storage system in which it is ultimately installed. This means that even in a complex storage system, individual storage cells can be treated individually so that they can control their individual working capacity and ageing conditions in an optimal manner accordingly. It is consequently also possible to achieve a longer service life for the corresponding storage system, for example a storage unit for an electric vehicle. At the same time, using the knowledge about the individual ageing properties of each individual storage cell 2, it is possible to assemble storage systems having particularly high performance features, such that storage systems which appear to be structurally identical from the outside can be used in different performance classes according to the demands thereof. For example, an electric vehicle with a higher performance label can, using the same structural format of the energy storage system, have a higher performance-even for only a short time if applicable-when correspondingly selected storage cells 2 are combined in this storage system.

### LIST OF REFERENCE SIGNS

2 Electrical storage cell
4 Reference data set
6 Reference storage cell
8 Electrical chemical operating characteristic
10 Database
12 Nyquist diagram
14 Data points
16 Electrochemical impedance spectroscopy
18 Conveyor line
20 Robot device
22 Assignment key
24 Family of ageing curves
26 Average data points
DOD Depth of discharge
SoC State of charge

What is claimed is:

1. A method for assessing an electrical storage cell, the method comprising
a) creating a reference data set relating to the ageing behavior of an individual reference storage cell of a specific type with regard to the charging and discharging behavior thereof;
b) creating a second reference data set of a second reference storage cell of the same type:
c) measuring an electrochemical operating characteristic of each reference storage cell for which a reference data set is created, and linking this operating characteristic & to the reference data set thereof;
d) saving at least two reference data sets of at least two reference storage cells of the same type and the associated links to the operating characteristic in a database;
e) measuring the electrochemical operating characteristic of a storage cell; and
f) comparing the measured operating characteristic of the storage cell with the operating characteristics of the reference storage cells saved in the database; and
g) assigning the storage cell on the basis of an assignment key to one of the operating characteristics saved in the database and the reference data set linked thereto.

2. The method as claimed in claim 1, wherein data points in the reference data set related g to the ageing behavior link three variables to each other, including a depth of discharge, a state of charge, and a number of equivalent full cycles of the reference storage cell possible for this.

3. The method as claimed in claim 2, wherein the reference data set contains at least five data points with linking of the three variables.

4. The method as claimed in claim 1, wherein at least five reference data sets with the respectively corresponding operating characteristics are saved in the database.

5. The method as claimed in claim 1, further comprising the reference data set relating to the ageing behavior by:
a) measuring at least two load cycles of the battery store by means of a high-precision coulometer, wherein one load cycle comprises a first discharging, during which a first charge amount from a first charge state to a second charge state is measured, followed by a first charging, during which a second charge amount from the second charge state to a third charge state is measured, and a second discharging, during which a third charge amount from the third charge state to a fourth charge state is measured, wherein the charging and discharging of the load cycle occurs between a lower voltage and an upper voltage of the battery store;
b) ascertaining a first charge transfer by difference between the fourth charge state and the second charge state, and ascertaining a second charge transfer by a difference between the third charge state and the first charge state;
c) ascertaining a capacitance loss from the difference between the first charge transfer and the second charge transfer,
performing a) to c) until a change the capacitance loss between two consecutive load cycles is below a threshold; and
determining an average capacitance loss on the basis of at least two capacitance losses.

6. The method as claimed in claim 1, wherein determining the electrochemical operating characteristic includes an electrochemical impedance spectroscopy.

7. The method as claimed in claim 6, wherein determining the electrochemical operating characteristic includes considering discrete frequencies of impedance spectrum obtained by the impedance spectroscopy.

8. (canceled)

9. The method as claimed in claim 1, further comprising, following assignment of a storage cell to a reference data set, producing a usage specification of the storage cell in a battery storage system.

10. The method as claimed in claim 1, further comprising, after assigning the storage cell to a reference data set, assigning the storage cell to a quality class.

11. The method as claimed in claim 10, wherein a quality criterion for the quality classes is characterized by a maximum number of equivalent full cycles in the reference data set.

12. The method as claimed in claim 10, wherein the quality criterion is characterized by the volume beneath a family of curves formed by the reference data set.
